(19) United States
(12) Patent Application Publication
(10) Pub. No.: US 2008/0297275 A1
(43) Pub. Date: Dec. 4, 2008

(54) DUAL CONFIGURATION FILTER CIRCUIT

(76) Inventors: Robert Keith Hollenbeck, Fort Wayne, IN (US); Justin Brubaker, Lafayette Hill, PA (US); Bruce Calvin Ley, Ossian, IN (US)

Correspondence Address: General Electric Company;GE Global Patent Operation, PO Box 861, 2 Corporate Drive, Suite 648, Shelton, CT, 06484, US

(21) Appl. No.: 11/757,275

(22) Filed: Jun. 1, 2007

(51) Int. Cl. H03H 7/00

(52) U.S. Cl. 333/181

(57) ABSTRACT

A low current leakage circuit for power source lines that include a first power line at one potential and a second power line at another potential with respect to the first power line and that carry energy to power a device is provided. The low leakage circuit may include a filter circuit connected in parallel with the device and between the first power line and the second power line. The filter circuit may have a junction in circuit with a local ground and a switch may be connected in series between the junction and the local ground. A method of reducing current leakage in a filter circuit for power source lines carrying energy for powering a device is also provided.

### BACKGROUND OF THE INVENTION

1. Field of the Invention

The subject matter described herein relates generally to devices and methods for filtering electrical energy and, more particularly, to devices and methods for filtering noise carried by, or induced in, power source lines.

2. Related Art

Electromagnetic noise, such as electromagnetic interference (sometimes referred to herein as “EMI”) is induced in power source lines and may originate from local sources. One local source known to create EMI is a switching power source. A typical device to reduce EMI is a power line filter circuit such as that described in U.S. Pat. No. 5,179,362. This patent illustrates in FIG. 2, a plurality of first inductors interposed between a live power line and a neutral power line. A first X-capacitor is interposed between the live line and the neutral line on a load side relative to the first inductors and a plurality of second inductors are interposed between the live line and the neutral line on the load side relative to the first X-capacitor. A Y-capacitor is interposed between the live line and the ground line as well as between the neutral line and the ground line on the load side relative to the second inductors. The Y-capacitors constitute a common mode filter between the first inductors and the second inductors in response to common mode noise.

However, to date, no suitable device or method of filtering electrical energy supplied by power source lines is available.

### BRIEF DESCRIPTION OF THE INVENTION

In accordance with an embodiment of the present invention, a low current leakage circuit for power source lines that comprise a first power line at one potential and a second power line at another potential with respect to the first power line and that carry energy to power a device is provided. The low leakage circuit may comprise a filter circuit connected in parallel with the device and between the first power line and the second power line. The filter circuit may have a junction in circuit with a local ground and a switch may be connected in series between the junction and the local ground.

In accordance with another embodiment of the present invention, a method of reducing current leakage in a filter circuit for power source lines carrying energy for powering a device is provided. The power source lines may comprise a first power line at one potential and a second power line at another potential with respect to the first power line. The method comprises connecting a filter circuit in parallel with the device and between the first power line and the second power line, the filter circuit having a junction in circuit with a local ground; connecting a switch in series between the junction and the local ground; and closing the switch when the device is energized.

### BRIEF DESCRIPTION OF THE DRAWINGS

The following detailed description is made with reference to the accompanying drawings, in which:

FIG. 1 is a circuit diagram showing one embodiment of a low leakage circuit in accordance with one embodiment of the present invention connected in circuit with an EMI filter and an inverter; and

FIG. 2 is a flow diagram showing a method of reducing leakage in filter circuits for power source lines in accordance with another embodiment of the present invention.

### DETAILED DESCRIPTION OF THE PREFERRED EMBODIMENT

One embodiment of the present invention concerns a device and a method for eliminating a leakage current in filter circuits such as those used for filtering electrical energy conducted by power source lines while maintaining relatively high filtering capability. It has been found that in current filter circuits, such as that described above and used in the energizing of a device, have a leakage current that increases when filtering capability is increased by using higher valued Y capacitors. One embodiment of the present invention overcomes this disadvantage by switching the Y capacitors to, e.g., green wire, chassis or local ground only when the inverter is operating and itself may be generating high frequency noise. By closing the switch upon energization of the device, a leakage current, measured when the device is de-energized, is eliminated. Accordingly, the capability of the filter circuit may be increased without consequence of a corresponding increase in leakage current.

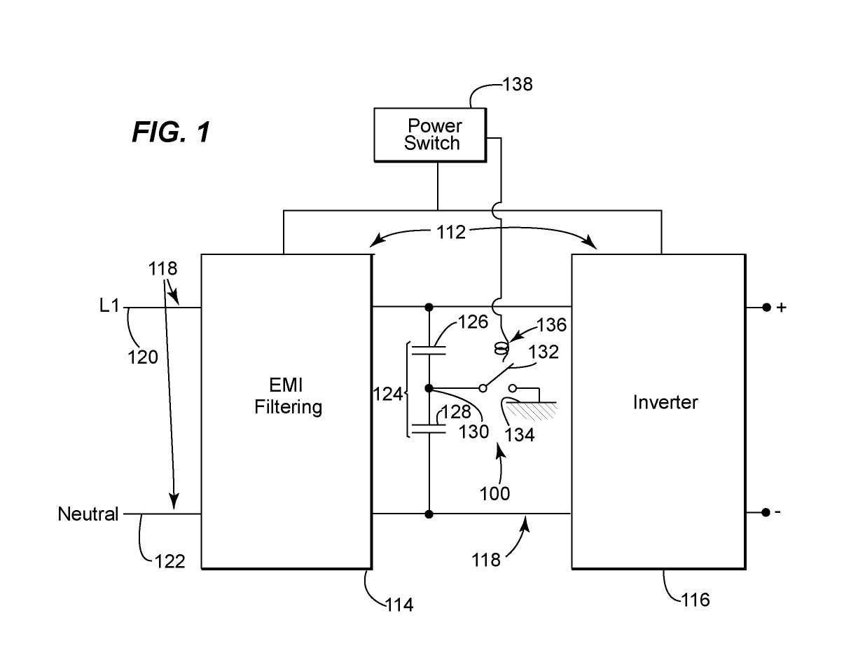

Referring now to FIG. 1, a low leakage circuit, in accordance with one embodiment of the present invention, is illustrated generally at 100. In this embodiment, the low leakage circuit 100 is connected in a parallel circuit arrangement with a device 112. The device 112 may comprise an EMI filter 114 and an inverter 116, although, it will be understood that any suitable device, for which it is desired that the power source lines be filtered, may be employed in the practice of the present invention. The EMI filter 114 may comprise additional circuit elements, e.g. a single stage or multiple stages, for eliminating noise such as a circuit element arrangement known to provide differential mode filtering. The inverter 116 may be any suitable known device for converting alternating current (AC) into direct current (DC).

In the illustrated embodiment of FIG. 1, the low leakage circuit 100 is connected to power source lines 118 that comprise a power line 120 that conducts electrical energy at one potential and a power line 122 that conducts electrical energy at another potential relative to the first power line 120. Examples of potentials for power lines 118 and 120 comprise one hundred and twenty (120) volts AC and neutral, respectively. It will be appreciated that other potentials and frequencies may be contemplated in the practice of the present invention such as 220 volts AC, 50 or 60 Hz (where each is 180 degrees out of phase with each other [single phase]) or multiple phase power systems.

In accordance with an embodiment of the invention, the low leakage circuit 100 comprises a filter circuit 124 and is shown in a configuration that shunts high frequency noise to ground when switch 132 is closed. The filter circuit 124 may comprise a pair of capacitors 126 and 128 each in circuit with a respective power line 120 and 122 and a junction 130. The capacitors 126 and 128 are illustrated as Y safety rated as they are connected to green wire safety ground by switch 132.

In accordance with this embodiment, the low leakage circuit 100 also comprises a normally open relay switch 132 that is interposed in series between the junction 130 and a local ground 134. The switch 132 may comprise an actuator 136 connected in circuit with a power switch 138 that is, in turn, connected with the device 112. The power switch 138 is configured to energize the actuator 136 and the device 112 whereby when the device is operating, the switch 132 is closed shunting the noise to ground. It will be understood that while the switch 132 and actuator 136 are shown as discreet components, other components might be utilized.

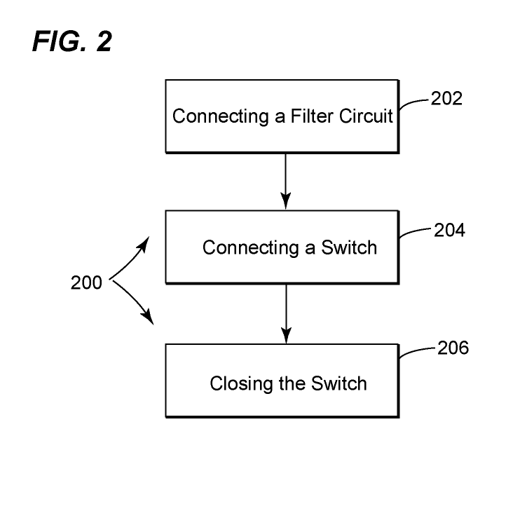

A method of reducing current leakage in a filter circuit for power source lines in accordance with another embodiment of the present invention is shown generally at 200 in FIG. 2. The power source lines may carry energy for powering a device and may comprise a first power line at one potential and a second power line at another potential with respect to the first power line. The method comprises, as shown at 202, connecting a filter circuit in parallel with the device and between the first power line and the second power line, the filter circuit having a junction in circuit with a local ground; as shown at 204, connecting a switch in series between the junction and the local ground; and as shown at 206, closing the switch when the device is energized.

While the present invention has been described in connection with what are presently considered to be the most practical and preferred embodiments, it is to be understood that the present invention is not limited to these herein disclosed embodiments. Rather, the present invention is intended to cover all of the various modifications and equivalent arrangements included within the spirit and scope of the appended claims.

What is claimed is:

1. A low current leakage circuit for power source lines carrying energy to power a device, the power source lines comprising a first power line at one potential and a second power line at another potential with respect to the first power line, the low leakage circuit comprising:
a filter circuit connected in parallel with the device and between the first power line and the second power line, the filter circuit having a junction being in circuit with a local ground; and
a switch being connected in series between the junction and the local ground.

2. The circuit of claim 1, wherein the filter circuit comprises a common mode filter circuit.

3. The circuit of claim 2, wherein the common mode filter circuit comprises a pair of Y-capacitors each being connected to a respective first or second power line and to the junction.

4. The circuit of claim 1, wherein the switch comprises a normally open relay switch connected to the device.

5. The circuit of claim 4, wherein the normally open relay switch is configured to close when the device is energized.

6. The circuit of claim 1, wherein the device comprises an electromagnetic interference filter circuit and an inverter.

7. The circuit of claim 1, wherein the energy comprises alternating current energy.

8. A method of reducing current leakage in a filter circuit for power source lines carrying energy for powering a device, the power source lines comprising a first power line at one potential and a second power line at another potential with respect to the first power line, comprising:
connecting a filter circuit in parallel with the device and between the first power line and the second power line, the filter circuit having a junction in circuit with a local ground;
connecting a switch in series between the junction and the local ground; and
closing the switch when the device is energized.

9. The method of claim 8, wherein the filter circuit comprises a common mode filter circuit.

10. The method of claim 9, wherein the common mode filter circuit comprises a pair of Y-capacitors each being connected to a respective first or second power line and to the junction.

11. The method of claim 8, wherein the switch comprises a normally open relay switch connected to the device.

12. The method of claim 8, wherein the device comprises an electromagnetic interference filter circuit and an inverter.

13. The method of claim 8, wherein the energy comprises alternating current energy.

14. A low current leakage circuit for power source lines carrying alternating current energy to power a device, the power source lines comprising a first power line at one potential and a second power line at another potential with respect to the first power line, the low leakage circuit comprising:
a common mode filter circuit connected in parallel with the device and between the first power line and the second power line, the filter circuit having a junction being in circuit with a local ground and a pair of Y-capacitors and each Y-capacitor being connected to a respective first or second power line and to the junction; and
a normally open relay switch being connected in series between the junction and the local ground, the normally open relay switch being configured to close when the device is energized.

15. The circuit of claim 14, wherein the device comprises an electromagnetic interference filter circuit and an inverter.
